(19) United States
(12) Patent Application Publication
(10) Pub. No.: US 2026/0262426 A1
(43) Pub. Date: Sep. 3, 2026

(54) DISPLAY DEVICE AND ELECTRONIC DEVICE INCLUDING THE SAME

(71) Applicant: Samsung Display Co., Ltd., Yongin-Si (KR)

(72) Inventors: Hyungguen Yoon, Yongin-si (KR); Ohjeong Kwon, Yongin-si (KR); Jongho Son, Yongin-si (KR)

(21) Appl. No.: 19/408,766

(22) Filed: Dec. 4, 2025

(30) Foreign Application Priority Data
Feb. 28, 2025 (KR) 10-2025-0026807

(51) Int. Cl. H10K 59/80; H10K 59/122

(52) U.S. Cl. CPC H10K 59/879; H10K 59/122; H10K 59/8792

(57) ABSTRACT

A display device includes a substrate, a display layer disposed on the substrate and including a light-emitting diode and a bank layer, and a light-controlling layer disposed on the display layer and including a light-blocking layer and a lens layer. The bank layer includes a lower opening defining an emission area of the light-emitting diode, the light-blocking layer includes an upper opening overlapping the lower opening, and the lens layer fills the upper opening. The lens layer has a concave upper surface in a thickness direction of the substrate.

### CROSS-REFERENCE TO RELATED APPLICATION

This application is based on and claims priority under 35 U.S.C. §119 to Korean Patent Application No. 10-2025-0026807, filed on February 28, 2025, in the Korean Intellectual Property Office, the disclosure of which is incorporated by reference herein in its entirety.

### BACKGROUND

### 1. Field

The present disclosure relates to a display device and an electronic device including the same.

### 2. Description of the Related Art

A display device is a device that presents a visual image representing data. A display device is used as a display unit not only for a small electronic device such as mobile phones, but also for a large electronic device such as televisions.

A display device includes a plurality of pixels that emit light in response to received electrical signals to display images to the outside. Each pixel includes a display element. For example, an organic light-emitting display device includes an organic light-emitting diode OLED as a display element.

Recently, as the purpose of a display device has diversified, various attempts in designing the display device have been made to improve the quality of the display device.

### SUMMARY

Embodiments of the present disclosure provide a display device having an improved display quality and an electronic device including the same.

Additional aspects and features of the present disclosure will be set forth in the description which follows and will be apparent from the description in conjunction with the accompanying drawings.

According to an embodiment, a display device includes a substrate, a display layer disposed on the substrate and including a light-emitting diode and a bank layer, and a light-controlling layer disposed on the display layer and including a light-blocking layer and a lens layer. The bank layer includes a lower opening defining an emission area of the light-emitting diode, the light-blocking layer includes an upper opening overlapping the lower opening, and the lens layer fills the upper opening. The lens layer has a concave upper surface in a thickness direction of the substrate.

In the thickness direction of the substrate, a thickness of a central portion of the lens layer may be less than a thickness of an edge portion of the lens layer.

In the thickness direction of the substrate, a thickness of the light-blocking layer may be equal to or less than the thickness of the edge portion of the lens layer.

In the thickness direction of the substrate, an upper surface of the light-blocking layer may be disposed at a height equal to an upper surface of the lens layer or disposed under the upper surface of the lens layer.

The light-emitting diode may be provided in plurality, and the lens layer may be provided in plurality. Each of the plurality of lens layers may be disposed on a corresponding light-emitting diode among the plurality of light-emitting diodes. Two lens layers disposed adjacent to each other among the plurality of lens layers may be disposed apart from each other, and the light-blocking layer may be interposed between the two lens layers.

When an imaginary fan is formed using the concave upper surface of the lens layer, a central angle of the imaginary fan may be about 10° to about 100°.

A refractive index of the lens layer may be about 1.6 to about 2.2.

The light-controlling layer may further include a low refractive layer disposed on the light-blocking layer and the lens layer and in direct contact with the lens layer. A refractive index of the lens layer may be greater than a refractive index of the low refractive layer.

A difference between the refractive index of the lens layer and the refractive index of the low refractive layer may be from 0.1 to 1.2.

The light-controlling layer may further include a polarizing film disposed on the light-blocking layer and the lens layer.

The lens layer may include a color filter material.

The light-controlling layer may further include a color filter layer disposed on the light-blocking layer and the lens layer.

The light-controlling layer may further include an overcoat layer disposed on the color filter layer. The color filter layer may include a plurality of color filters, and each of the plurality of color filters is disposed apart from each other. The overcoat layer may fill gaps between color filters disposed adjacent to each other.

According to an embodiment, a display device includes a substrate, a display layer including a light-emitting diode disposed on the substrate, an input-sensing layer disposed on the display layer, and a light-controlling layer disposed on the input-sensing layer. The light-controlling layer includes a light-blocking layer including an opening overlapping an emission area of the light-emitting diode, a lens layer disposed in the opening of the light-blocking layer, and a low refractive layer disposed on the light-blocking layer and the lens layer and having a refractive index less than the lens layer. In a thickness direction of the substrate, an upper surface of the lens layer facing the low refractive layer has a concave curved surface.

In the thickness direction of the substrate, an upper surface of the light-blocking layer may be disposed at a height equal to the upper surface of the lens layer or disposed under the upper surface of the lens layer.

The light-controlling layer may further include a polarizing film disposed on the low refractive layer.

The lens layer may include a color filter material.

The light-controlling layer may further include a color filter layer disposed on the low refractive layer.

According to an embodiment, an electronic device includes a display device providing images, and a housing accommodating the display device. The display device includes a substrate, a display layer disposed on the substrate and including a light-emitting diode and a bank layer, and a light-controlling layer disposed on the display layer and including a light-blocking layer and a lens layer. The bank layer includes a lower opening defining an emission area of the light-emitting diode, the light-blocking layer includes an upper opening overlapping the lower opening, and the lens layer fills the upper opening. The lens layer has a concave upper surface in a thickness direction of the substrate.

In the thickness direction of the substrate, an upper surface of the light-blocking layer may be disposed at a height equal to an upper surface of the lens layer or disposed under the upper surface of the lens layer.

### BRIEF DESCRIPTION OF THE DRAWINGS

The above and other aspects, features, and advantages of the present disclosure will become more apparent from the following description taken in conjunction with the accompanying drawings.

FIG. 1 is a schematic perspective view illustrating a display device according to an embodiment.

FIG. 2 is a schematic equivalent circuit diagram illustrating a light-emitting diode included in one of sub-pixels of a display device and a sub-pixel circuit connected to the light-emitting diode according to an embodiment.

FIG. 3 is a schematic cross-sectional view of a display device, taken along a line I-I' of FIG. 1, according to an embodiment.

FIG. 4 is a schematic plan view illustrating a portion of a display device according to an embodiment.

FIG. 5 is a schematic cross-sectional view of a portion of a display device according to an embodiment.

FIGS. 6A to 6C are schematic enlarged cross-sectional views of a portion of the display device, which corresponds to a region VI of FIG. 5 according to an embodiment.

FIG. 7A is a graph showing brightness of emitted light according to a measurement angle of light emitted from an organic light-emitting diode included in a display device according to an embodiment.

FIG. 7B is a graph showing reflective brightness according to a measurement angle of external light incident to a display device according to an embodiment.

FIG. 8 is a schematic cross-sectional view of a display device according to an embodiment.

FIG. 9 is a schematic cross-sectional view of a portion of a display device according to an embodiment.

FIG. 10 is a block diagram of an electronic device according to an embodiment.

FIG. 11 is a schematic view of electronic devices according to various embodiments.

### DETAILED DESCRIPTION

Hereinafter, specific embodiments of the present disclosure are explained in detail with reference to the accompanying drawings. Like numerals refer to like elements throughout. In this regard, embodiments of the present disclosure may have different forms and should not be construed as being limited to the descriptions set forth herein. Accordingly, the embodiments are merely described below, by referring to the drawings, to explain aspects of the present disclosure. As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.”

As the present disclosure allows for various changes and can have numerous embodiments, certain embodiments will be illustrated in the drawings and described in detail in the written description. Effects and features of the present disclosure as well as methods for achieving them will be described more fully with reference to embodiments described below in detail with reference to the drawings. However, the present disclosure is not limited to embodiments described below and may be implemented in various forms.

Hereinafter, embodiments will be described with reference to the accompanying drawings. Those components that are the same as or similar to in their functionalities or structures, etc. are denoted using the same reference numerals regardless of the figure number, and redundant descriptions thereof are omitted.

The terms, such as "first" and "second," may be used to describe various components, but the elements are not limited by the terms. The above terms are used only for the purpose of distinguishing one component from another.

The singular expression, such as “a” and “an,” used herein are intended to include plural forms, unless it has a clearly different meaning in the context.

It will be further understood that the terms, such as "comprise" or "include," as used herein specify the presence of a certain characteristics or element, or a combination thereof, but do not preclude the presence or addition of one or more other characteristics, elements, or combinations thereof.

When a layer, region, or element is referred to as being “formed on” another layer, region, or element, it may be directly or indirectly formed on the other layer, region, or element. That is, for example, one or more intervening layers, regions, or elements may be present therebetween.

Sizes of elements in the drawings may be exaggerated or reduced for convenience of explanation. In other words, since the size and thickness of each element shown in the drawings are arbitrarily illustrated for convenience of description, the following embodiments are not necessarily limited thereto.

The order of the process or method understood in the description of the processing process, manufacturing method, etc. may be different from the described order. For example, two processes successively described may be performed substantially at the same time or performed in an order opposite to the described order.

It will be understood that when a layer, region, or component is referred to as being "connected" to another layer, region, or component, it may be "directly connected" to the other layer, region, or component, or may be "indirectly connected" to the other layer, region, or component with one or more intervening layers, regions, or components interposed therebetween. For example, when a layer, region, or element is referred to as being electrically connected to another layer, region, or element, it represents not only a case where the layer, region, or element is directly electrically connected to the other layer, region, or element, but also a case where the layer, region, or element may be indirectly electrically connected to the other layer, region, or element with an intervening layer, region, or element interposed therebetween.

The x-axis, y-axis and z-axis are not limited to three axes on the rectangular coordinate system, and may be interpreted in a broader sense including the same. For example, the x-axis, y-axis, and z-axis may be perpendicular to one another, or may represent different directions that are not perpendicular to one another.

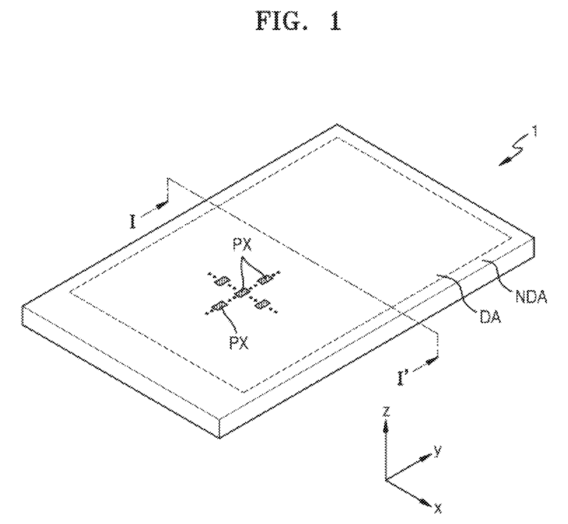

FIG. 1 is a schematic perspective view illustrating a display device 1 according to an embodiment.

Referring to FIG. 1, the display device 1 may include a display area DA, and a peripheral area NDA outside the display area DA. The display device 1 may be configured to display images through an array of sub-pixels PX arranged two-dimensionally in the display area DA.

Each sub-pixel PX of the display device 1 is a region that may emit light of a preset color. The display device 1 may be configured to display images by using light from the sub-pixels PX. As an example, each sub-pixel PX may be configured to emit red, green, blue, or white light.

Each of the sub-pixels PX may be configured to emit light of a preset color using a light-emitting diode, for example, an organic light-emitting diode. Each organic light-emitting diode may emit, for example, red, green, blue, or white light. Each organic light-emitting diode may be connected to a sub-pixel circuit PC including a thin-film transistor and a capacitor.

The peripheral area NDA is a region that does not display images and may surround at least a portion of the display area DA. A driver or a main power line configured to provide electrical signals or power to the sub-pixel circuits PC may be disposed in the peripheral area NDA. A pad may be arranged in the peripheral area NDA. The pad is a region to which electronic elements or a printed circuit board may be electrically connected.

As shown in FIG. 1, the display area DA may have a polygonal shape including a quadrangular shape. For example, the display area DA may have a rectangular shape with the horizontal length greater than the vertical length, a rectangular shape with the horizontal length less than the vertical length, or a square shape. However, the present disclosure is not limited thereto. For example, the display area DA may have various shapes such as an elliptical shape or a circular shape.

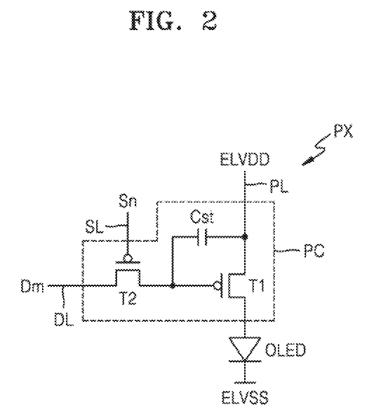

FIG. 2 is a schematic equivalent circuit diagram illustrating a light-emitting diode included in a sub-pixel of the display device, and a sub-pixel circuit PC connected to the light-emitting diode according to an embodiment.

Referring to FIG. 2, the sub-pixel of the display device may include a light-emitting diode, for example, an organic light-emitting diode OLED, and the sub-pixel circuit PC connected to the light-emitting diode. The sub-pixel circuit PC may include a first thin-film transistor T1, a second thin-film transistor T2, and a storage capacitor Cst.

The second thin-film transistor T2 is a switching thin-film transistor. The second thin-film transistor T2 may be electrically connected to a scan line SL and a data line DL, and configured to transfer a data signal Dm to the first thin-film transistor T1 in response to a scan voltage or a scan signal Sn. The data signal may be input from the data line DL, and the scan voltage may be input from the scan line SL.

The storage capacitor Cst may be electrically connected between the second thin-film transistor T2 and a driving voltage line PL, and configured to store a voltage corresponding to the difference between a voltage transferred from the second thin-film transistor T2 and a driving voltage ELVDD supplied from the driving voltage line PL.

The first thin-film transistor T1 is a driving thin-film transistor. The first thin-film transistor T1 may be electrically connected to the driving voltage line PL and the storage capacitor Cst, and configured to control a driving current in response to the voltage stored in the storage capacitor Cst. The driving current may flow from the driving voltage line PL to the organic light-emitting diode OLED when the first thin-film transistor T1 is turned on. The organic light-emitting diode OLED may be configured to emit light having a preset brightness corresponding to the driving current. A sub-pixel electrode (e.g., an anode) of the organic light-emitting diode OLED may be connected to the sub-pixel circuit PC. An opposite electrode (e.g., a cathode) of the organic light-emitting diode OLED may receive a common voltage ELVSS.

Although FIG. 2 shows that the sub-pixel circuit PC includes two thin-film transistors and one storage capacitor, the number of thin-film transistors or the number of storage capacitors may be variously changed depending on the design of the sub-pixel circuit PC.

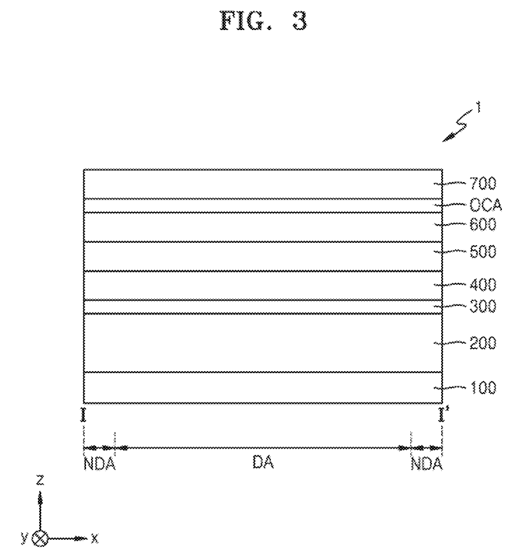

FIG. 3 is a schematic cross-sectional view of the display device 1, taken along a line I-I' of FIG. 1, according to an embodiment.

Referring to FIG. 3, the display device 1 may include a substrate 100, a display layer 200, a low reflective layer 300, an encapsulation layer 400, a touch sensor layer 500, a light-controlling layer 600, an adhesive layer OCA, and a cover window 700.

The substrate 100 may include glass or a polymer resin. For example, the polymer resin may include polyethersulfone, polyacrylate, polyetherimide, polyethylene naphthalate, polyethylene terephthalate, polyphenylene sulfide, polyarylate, polyimide, polycarbonate, cellulose acetate propionate, or the like. The substrate 100 including the polymer resin may be flexible, rollable, or bendable. The substrate 100 may have a multi-layered structure including a layer that includes a polymer resin and an inorganic layer (not shown).

The display layer 200 may include a light-emitting diode, a thin-film transistor, and a plurality of insulating layers between the thin-film transistor and the light-emitting diode. The thin-film transistor may be electrically connected to the light-emitting diode, for example, an organic light-emitting diode.

The low reflective layer 300 may be disposed on the display layer 200, and the encapsulation layer 400 may be disposed on the low reflective layer 300. For example, the display layer 200 or the low reflective layer 300 may be sealed by the encapsulation layer 400. However, the present disclosure is not limited thereto. For example, the low reflective layer 300 may be omitted. In this case, the encapsulation layer 400 may be directly disposed on the display layer 200. The encapsulation layer 400 may include at least one inorganic encapsulation layer and at least one organic encapsulation layer.

The present disclosure, however, is not limited thereto. For example, an encapsulation substrate (not shown) including glass may be provided instead of the encapsulation layer 400. The encapsulation substrate may be disposed on the display layer 200, and the display layer 200 may be disposed between the substrate 100 and the encapsulation substrate. If there may be a gap between the encapsulation substrate and the display layer 200, the gap may be filled with a filler.

The touch sensor layer 500 may be disposed on the encapsulation layer 400. The touch sensor layer 500 may sense an external input, for example, a touch of an object such as a finger or a stylus pen, and the display device 1 may obtain coordinate information corresponding to the touched position. The touch sensor layer 500 may include a plurality of touch electrodes and a plurality of trace lines. Each of the plurality of touch electrodes is connected to a corresponding trace line. The touch sensor layer 500 may sense an external input using a mutual capacitive method or a self-capacitive method.

The touch sensor layer 500 may be directly formed on the encapsulation layer 400. However, the present disclosure is not limited thereto. For example, the touch sensor layer 500 may be attached to the encapsulation layer 400 using an adhesive layer such as an optically clear adhesive.

The light-controlling layer 600 may be disposed on the touch sensor layer 500. The light-controlling layer 600 may reduce the reflection of external light incident toward the display device 1 from the outside through the cover window 700.

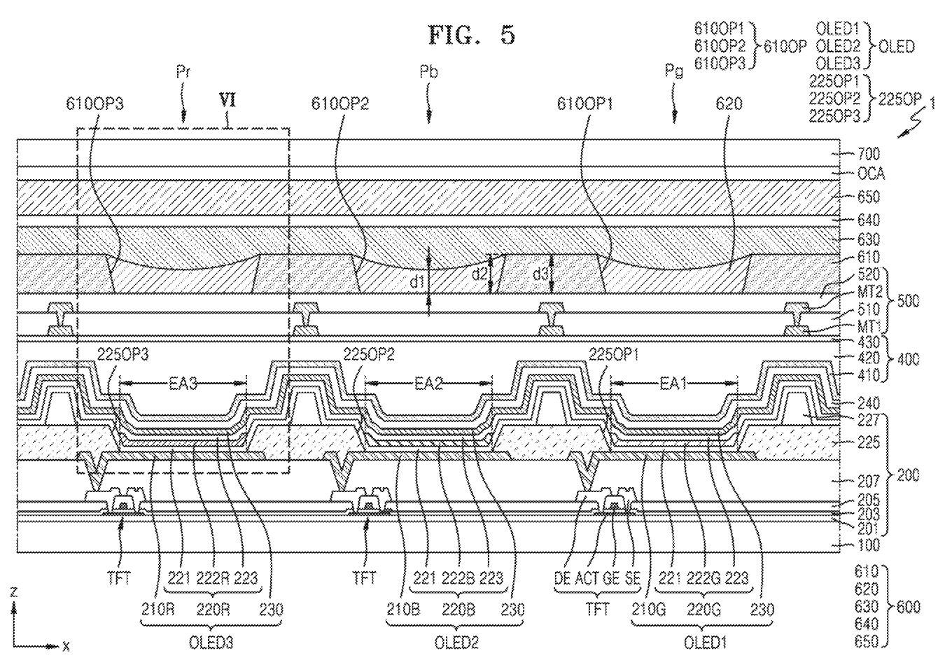

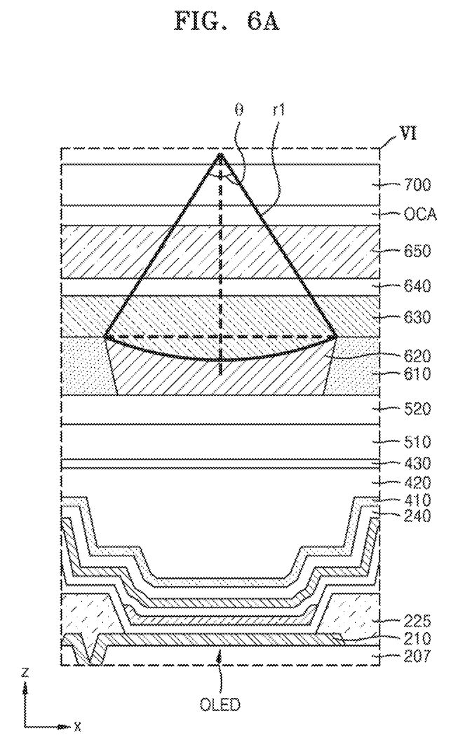

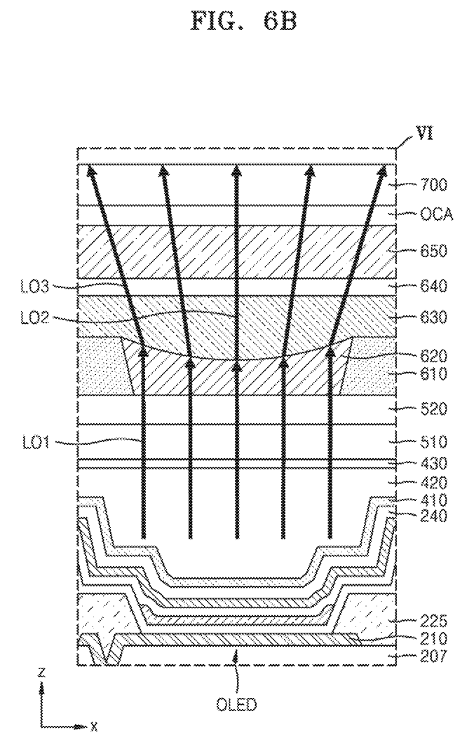

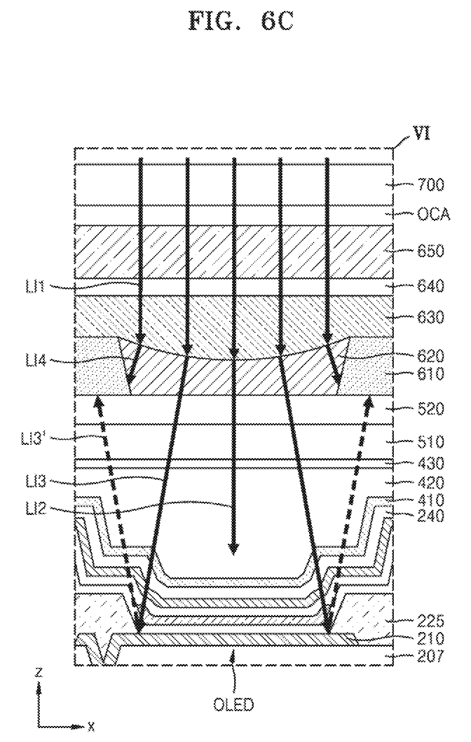

The light-controlling layer 600 may reduce reflection of external light. According to an embodiment, the light-controlling layer 600 may include a light-blocking layer and a lens layer. Reflection of external light may be reduced through the light-blocking layer that absorbs light and the lens layer having a concave upper surface. The lens layer is described in detail with reference to FIGS. 5 to 6C. For example, the light-controlling layer 600 may further include a polarizing film. For example, the light-controlling layer 600 may include a circular polarizer having an anti-reflection function. For example, the light-controlling layer 600 may further include color filters. The color filters may be arranged in consideration of colors of light emitted from each of the light-emitting diodes of the display layer 200.

The cover window 700 may be disposed on the light-controlling layer 600. The cover window 700 may protect layers disposed under the cover window 700. The cover window 700 may be formed separately and then attached to the light-controlling layer 600 using the adhesive layer OCA disposed between the cover window 700 and the light-controlling layer 600. The adhesive layer OCA may be, for example, an optically clear adhesive. However, the present disclosure is not limited thereto. For example, the cover window 700 may be directly formed on the light-controlling layer 600.

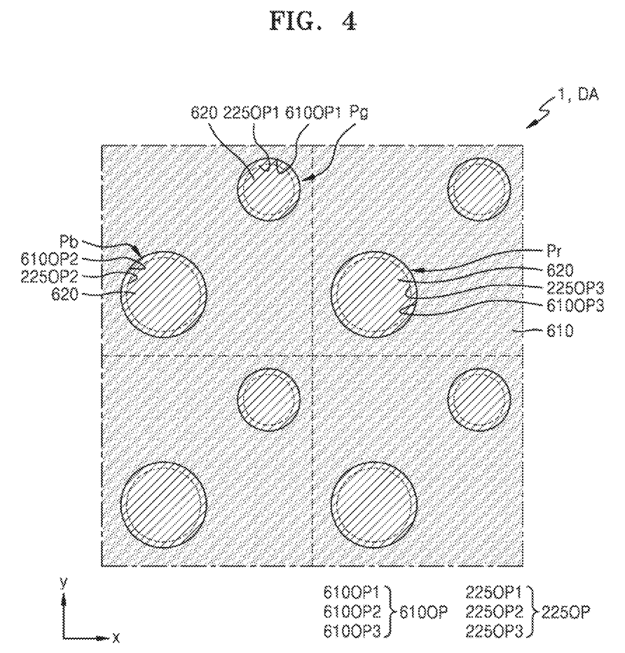

FIG. 4 is a schematic plan view illustrating a portion of the display device 1 according to an embodiment. For convenience of explanation, FIG. 4 shows a light-blocking layer 610 in a plan view.

Referring to FIG. 4, the display device 1 may include the plurality of sub-pixels. The plurality of sub-pixels may include a red sub-pixel Pr, a blue sub-pixel Pb, and a green sub-pixel Pg. Each of the plurality of sub-pixels may include a light-emitting diode emitting light of a corresponding color. For example, the red sub-pixel Pr may be configured to emit light in a wavelength band of about 580 nm to about 780 nm, the blue sub-pixel Pb may be configured to emit light in a wavelength band of about 380 nm to about 495 nm, and the green sub-pixel Pg may be configured to emit light in a wavelength band of about 495 nm to about 580 nm.

A bank layer 225 (see FIG. 5) may include a lower opening 225OP defining an emission area of each sub-pixel. The light-emitting diode may include the sub-pixel electrode, the opposite electrode, and an emission layer disposed between the sub-pixel electrode and the opposite electrode. The bank layer 225 (see FIG. 5) may cover the edge of the sub-pixel electrode, and the lower opening 225OP of the bank layer 225 (see FIG. 5) may expose the central portion of the sub-pixel electrode. The emission layer of the light-emitting diode may be disposed in the lower opening 225OP of the bank layer 225 (see FIG. 5). Specifically, the bank layer 225 (see FIG. 5) may include a first lower opening 225OP1 defining an emission area of the green sub-pixel Pg, a second lower opening 225OP2 defining an emission area of the blue sub-pixel Pb, and a third lower opening 225OP3 defining an emission area of the red sub-pixel Pr.

As shown in FIG. 4, each of the first to third lower openings 225OP1, 225OP2, and 225OP3 may have a circular shape when viewed in a direction perpendicular to the substrate 100 (see FIG. 5). In other words, an emission area of each of the green sub-pixel Pg, the blue sub-pixel Pb, and the red sub-pixel Pr may have a circular shape when viewed in a direction perpendicular to the substrate 100 (see FIG. 5). However, the present disclosure is not limited thereto. For example, each of the first to third lower openings 225OP1, 225OP2, and 225OP3 may have various shape, such as an elliptical shape or a polygonal shape.

The light-blocking layer 610 of the light-controlling layer 600 (see FIG. 3) described above may be disposed on the bank layer 225 (see FIG. 5) and the light-emitting diode. The light-blocking layer 610 may include an upper opening 610OP corresponding to each of the plurality of emission areas. Specifically, the light-blocking layer 610 may include a first upper opening 610OP1 corresponding to the green sub-pixel Pg and overlapping the first lower opening 225OP1, a second upper opening 610OP2 corresponding to the blue sub-pixel Pb and overlapping the second lower opening 225OP2, and a third upper opening 610OP3 corresponding to the red sub-pixel Pr and overlapping the third lower opening 225OP3.

The lens layer 620 of the light-controlling layer 600 (see FIG. 3) may be disposed in the upper opening 610OP of the light-blocking layer 610. The lens layer 620 may be equally disposed in all of the first upper opening 610OP1, the second upper opening 610OP2, and the third upper opening 610OP3. The lens layer 620 is described in detail with reference to FIGS. 5 to 6C.

Like the lower opening 225OP, the upper opening 610OP may have a circular shape when viewed in a direction perpendicular to the substrate 100 (see FIG. 5). Although described below, the circular shape of the upper opening 610OP may allow the upper surface of the lens layer 620 to have an optimized curved surface. However, the present embodiment is not limited thereto and the shape of the upper opening 610OP may be modified according to the shape of the lower opening 225OP. For example, the shape of the upper opening 610OP may be an elliptical shape or a polygonal shape.

The size of the upper opening 610OP may be greater than the size of the lower opening 225OP to increase the efficiency of light emitted from the emission area. For example, the size of the planar area of the first upper opening 610OP1 may be greater than the size of the planar area of the first lower opening 225OP1. That is, in a plan view, the bank layer 225 (see FIG. 5) may be disposed to further protrude toward the emission area (or the center of each sub-pixel) than the light-blocking layer 610. However, the present disclosure is not limited thereto. For example, the size of the upper opening 610OP may be equal to or substantially same as the size of the lower opening 225OP.

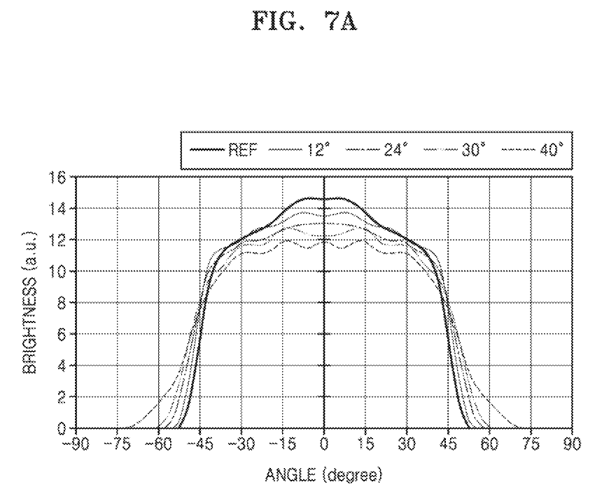

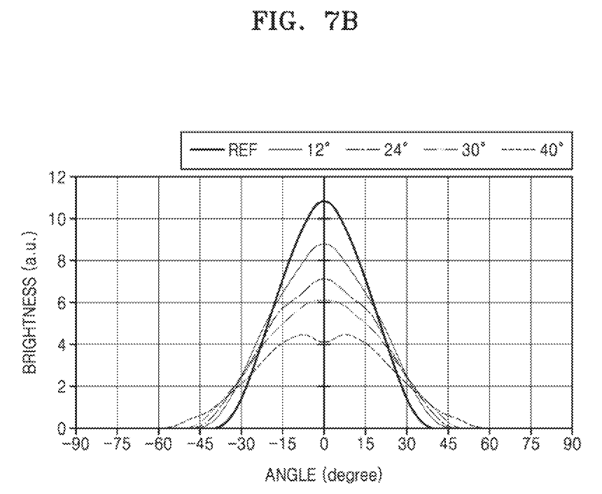

FIG. 5 is a schematic cross-sectional view of a portion of the display device 1 according to an embodiment. FIGS. 6A to 6C are schematic enlarged cross-sectional views of a portion of the display device 1, which corresponds to a region VI of FIG. 5 according to an embodiment. FIG. 7A is a graph showing brightness of emitted light according to an angle of light emitted from an organic light-emitting diode included in the display device 1 according to an embodiment. FIG. 7B is a graph showing reflective brightness according to a measurement angle of external light incident to the display device 1 according to an embodiment.

Referring to FIG. 5, the display device 1 may include the substrate 100, the display layer 200, the encapsulation layer 400, the touch sensor layer 500, the light-controlling layer 600, the adhesive layer OCA, and the cover window 700.

The display device 1 may include the sub-pixels disposed in the display area DA (see FIG. 4). Each of the sub-pixels may be configured to emit red, green, or blue light. The sub-pixels may include a first sub-pixel, a second sub-pixel and a third sub-pixel, each of which is configured to emit light of a different color from each other. For example, the sub-pixels may include the green sub-pixel Pg, the blue sub-pixel Pb, and the red sub-pixel Pr. Each of the green sub-pixel Pg, the blue sub-pixel Pb, and the red sub-pixel Pr may be provided in plurality.

The display layer 200 may be disposed on the substrate 100. The display layer 200 may include a sub-pixel circuit layer and a light-emitting diode layer. The sub-pixel circuit layer may include a thin-film transistor TFT, a buffer layer 201, a gate insulating layer 203, an interlayer insulating layer 205, and a planarization layer 207.

The buffer layer 201 may be disposed on the substrate 100. The buffer layer 201 may reduce or block penetration of foreign materials, moisture, or external air from below the substrate 100, and provide a flat surface on the substrate 100. The buffer layer 201 may include an inorganic material, an organic material, or an organic/inorganic composite material, and include a single layer or a multi-layer including an inorganic material and an organic material. The inorganic material may include oxide or nitride. A barrier layer (not shown) may be further disposed between the substrate 100 and the buffer layer 201, and may block penetration of external air. For example, the buffer layer 201 may include silicon oxide or silicon nitride.

The thin-film transistor TFT may be disposed on the buffer layer 201. The thin-film transistor TFT may include a semiconductor layer ACT, a gate electrode GE, a source electrode SE, and a drain electrode DE. The thin-film transistor TFT may be connected to an organic light-emitting diode to drive the organic light-emitting diode.

The semiconductor layer ACT may be disposed on the buffer layer 201. The semiconductor layer ACT may include polycrystalline silicon or amorphous silicon. However, the present disclosure is not limited thereto. For example, the semiconductor layer ACT may include an oxide of at least one of indium (In), gallium (Ga), stannum (Sn), zirconium (Zr), vanadium (V), hafnium (Hf), cadmium (Cd), germanium (Ge), chrome (Cr), titanium (Ti), and zinc (Zn). The semiconductor layer ACT may include a channel region, a source region, and a drain region. The source region and the drain region may be doped with impurities, and the channel region may be disposed between the source region and the drain region.

The gate electrode GE, the source electrode SE, and the drain electrode DE may include various conducive materials. For example, the gate electrode GE may include at least one of molybdenum (Mo), aluminum (Al), copper (Cu), and titanium (Ti). For example, the gate electrode GE may be a single Mo layer or have a three-layered structure including a Mo layer, an Al layer, and a Mo layer. For example, each of the source electrode SE and the drain electrode DE may include at least one of cupper (Cu), titanium (Ti), and aluminum (Al). For example, the source electrode SE and the drain electrode DE may have a three-layered structure including a Ti layer, an Al layer, and a Ti layer.

The gate insulating layer 203 may be disposed between the semiconductor layer ACT and the gate electrode GE to insulate the semiconductor layer ACT from the gate electrode GE. The interlayer insulating layer 205 may be disposed on the gate electrode GE, and the source electrode SE and the drain electrode DE may be disposed on the interlayer insulating layer 205.

Each of the gate insulating layer 203 and the interlayer insulating layer 205 may include an inorganic material such as silicon oxide, silicon nitride, or silicon oxynitride. The gate insulating layer 203 and the interlayer insulating layer 205 may be formed through chemical vapor deposition (CVD) or atomic layer deposition (ALD).

The planarization layer 207 may be disposed on the thin-film transistor TFT. To provide a flat upper surface, after forming the planarization layer 207, chemical and mechanical polishing may be performed on the upper surface of the planarization layer 207. The planarization layer 207 may include a general-purpose polymer such as photosensitive polyimide, polyimide, polycarbonate (PC), benzocyclobutene (BCB), polyimide, hexamethyldisiloxane (HMDSO), polymethylmethacrylate (PMMA) or polystyrene (PS), polymer derivatives having a phenol-based group, an acryl-based polymer, an imide-based polymer, an aryl ether-based polymer, an amide-based polymer, a fluorine-based polymer, a p-xylene-based polymer, or a vinyl alcohol-based polymer. Although FIG. 5 shows that the planarization layer 207 is a single layer, the planarization layer 207 may include a multi-layer. Each of the sub-pixel electrodes 210G, 210B, and 210R of the first to third organic light-emitting diodes OLED1, OLED2, and OLED3 may be electrically connected to the thin-film transistor TFT through a contact hole extending through the planarization layer 207.

The light-emitting diode layer may be disposed on the sub-pixel circuit layer. According to an embodiment, the light-emitting diode layer may include the first to third organic light-emitting diodes OLED1, OLED2, and OLED3, the bank layer 225, and a spacer 227.

The first organic light-emitting diode OLED1, the second organic light-emitting diode OLED2, and the third organic light-emitting diode OLED3 may be disposed on the sub-pixel circuit layer. The first organic light-emitting diode OLED1 may include a stacking structure of the first sub-pixel electrode 210G, a first intermediate layer 220G including a first common layer 221, a first emission layer 222G, and a second common layer 223, and an opposite electrode 230. The second organic light-emitting diode OLED2 may include a stacking structure of the second sub-pixel electrode 210B, a second intermediate layer 220B including the first common layer 221, a second emission layer 222B, and the second common layer 223, and the opposite electrode 230. The third organic light-emitting diode OLED3 may include a stacking structure of the third sub-pixel electrode 210R, a third intermediate layer 220R including the first common layer 221, a third emission layer 222R, and the second common layer 223, and the opposite electrode 230.

The first to third sub-pixel electrodes 210G, 210B, and 210R may be disposed on the planarization layer 207. The first to third sub-pixel electrodes 210G, 210B, and 210R may be disposed apart from each other. The first to third sub-pixel electrodes 210G, 210B, and 210R may include a reflective electrode. For example, each of the first to third sub-pixel electrodes 210G, 210B, and 210R may include a reflective layer and a transparent or semi-transparent conductive layer on the reflective layer. The reflective layer may include silver (Ag), magnesium (Mg), aluminum (Al), platinum (Pt), palladium (Pd), gold (Au), nickel (Ni), neodymium (Nd), iridium (Ir), chrome (Cr), or a compound thereof. The transparent or semi-transparent electrode layer may include at least one of indium tin oxide (ITO), indium zinc oxide (IZO), zinc oxide (ZnO), indium oxide (In₂O₃), indium gallium oxide (IGO), and aluminum zinc oxide (AZO).

The bank layer 225 may be disposed on the planarization layer 207 and overlap a portion of each of the first to third sub-pixel electrodes 210G, 210B, and 210R. The bank layer 225 may have a lower opening 225OP extending to each of the first to third sub-pixel electrodes 210G, 210B, and 210R and exposing the central portion of each of the first to third sub-pixel electrodes 210G, 210B, and 210R. The bank layer 225 may cover the edge of each of the first to third sub-pixel electrodes 210G, 210B, and 210R and prevent arcs and the like from occurring at the edge of the sub-pixel electrode by increasing a distance between the edge of the sub-pixel electrode and the opposite electrode 230.

The lower opening 225OP of the bank layer 225 may define each of first to third emission areas EA1, EA2, and EA3 of the first to third organic light-emitting diodes OLED1, OLED2, and OLED3 included in the sub-pixels. As shown in FIG. 5, the bank layer 225 may include the first lower opening 225OP1 that defines the first emission area EA1 of the first organic light-emitting diode OLED1 of the green sub-pixel Pg. In addition, the bank layer 225 may include the second lower opening 225OP2 defining the second demission area EA2 of the second organic light-emitting diode OLED2 of the blue sub-pixel Pb, and include the third lower opening 225OP3 defining the third demission area EA3 of the third organic light-emitting diode OLED3 of the red sub-pixel Pr.

The bank layer 225 may include an organic insulating material. However, the present disclosure is not limited thereto. For example, the bank layer 225 may include an inorganic insulating material such as silicon nitride or silicon oxide. For example, the bank layer 225 may include an organic insulating material and an inorganic insulating material.

The bank layer 225 may include a light-blocking material. For example, the light-blocking material of the bank layer 225 may be black. The light-blocking material may include carbon black, carbon nanotubes, a resin or paste including black dye, metal particles, for example, nickel, aluminum, molybdenum, and an alloy thereof, metal oxide particles or metal nitride particles. When the bank layer 225 includes a light-blocking material, external light reflection caused by metal structures arranged below the bank layer 225 may be reduced.

The spacer 227 may be disposed on the bank layer 225. The spacer 227 may include an organic insulating material such as polyimide. However, the present disclosure is not limited thereto. For example, the spacer 227 may include an inorganic insulating material such as silicon nitride or silicon oxide, or include an organic insulating material and an inorganic insulating material. According to an embodiment, the spacer 227 may include a material different from that of the bank layer 225 including the light-blocking material. The spacer 227 and the bank layer 225 may be respectively formed in separate processes. However, the present disclosure is not limited thereto. For example, the spacer 227 and the bank layer 225 may include the same material, and the bank layer 225 and the spacer 227 may be simultaneously formed during a mask process that uses a half-tone mask.

The intermediate layer 220G, 220B and 220R may be disposed on the first to third sub-pixel electrodes 210G, 210B, and 210R and the bank layer 225. As described above, the intermediate layer 220G, 220B and 220R may include the first common layer 221, the emission layer 222G, 222B and 222R, and the second common layer 223.

The first to third emission layers 222G, 222B, and 222R may be disposed inside the first to third lower openings 225OP1, 225OP2, and 225OP3 of the bank layer 225. The first to third emission layers 222G, 222B, and 222R may include an organic material including a fluorescent or phosphorous material that may emit green, blue, or red light. The organic material may include a low molecular weight organic material or a polymer organic material.

The first common layer 221 may be disposed under the emission layer, and the second common layer 223 may be disposed on the emission layer. The first common layer 221 may include, for example, a hole transport layer (HTL), or include an HTL and a hole injection layer (HIL). The second common layer 223 may include, for example, an electron transport layer (ETL), or include an ETL and an electron injection layer (EIL). Depending on the design of the display device 1, the second common layer 223 may be omitted.

According to an embodiment, the emission layer is disposed in each of the first to third lower openings 225OP1, 225OP2, and 225OP3 of the bank layer 225 to correspond to each sub-pixel. In contrast, each of the first common layer 221 and the second common layer 223 may be integrally formed to cover the substrate 100 entirely. In other words, the first common layer 221 and the second common layer 223 may each be integrally formed to cover the display area DA (see FIG. 4) of the substrate 100 entirely.

The opposite electrode 230 may be a cathode which is an electron injection electrode. The opposite electrode 230 may include a conductive material having a low work function. For example, the opposite electrode 230 may include a (semi) transparent layer including silver (Ag), magnesium (Mg), aluminum (Al), platinum (Pt), palladium (Pd), gold (Au), nickel (Ni), neodymium (Nd), and iridium (Ir), chrome (Cr), lithium (Li), calcium (Ca), or an alloy thereof. The opposite electrode 230 may further include a layer on the (semi) transparent layer, the layer including ITO, IZO, ZnO, or In₂O₃.

According to an embodiment, a capping layer 240 may be disposed on the display layer 200. The capping layer 240 may be disposed on the first to third organic light-emitting diodes OLED1, OLED2, and OLED3. The capping layer 240 may improve a light-emission efficiency of the first to third organic light-emitting diodes OLED1, OLED2, and OLED3 due to the principle of constructive interference.

The capping layer 240 may be an organic capping layer including an organic material, an inorganic capping layer including an inorganic material, or a composite capping layer including an organic material and an inorganic material. For example, the capping layer 240 may include a carbocyclic compound, a heterocyclic compound, an amine group-containing compound, porphine derivatives, phthalocyanine derivatives, naphthalocyanine derivatives, alkali metal complexes, alkali earth metal complexes, or an arbitrary combination thereof. The carbocyclic compound, heterocyclic compound and amine group-containing compound may be optionally substituted with substituents including O, N, S, Se, Si, F, Cl, Br, I, or any combination thereof.

The encapsulation layer 400 may be disposed on the capping layer 240. The encapsulation layer 400 may include at least one inorganic encapsulation layer and at least one organic encapsulation layer. For example, as shown in FIG. 5, the encapsulation layer 400 may include a first inorganic encapsulation layer 410, an organic encapsulation layer 420, and a second inorganic encapsulation layer 430 that are sequentially stacked.

The first inorganic encapsulation layer 410 and the second inorganic encapsulation layer 430 may include an inorganic insulating material such as silicon oxide, silicon nitride, silicon oxynitride, aluminum oxide, titanium oxide, tantalum oxide, hafnium oxide, or zinc oxide. The first and second inorganic encapsulation layers 410 and 430 may include a single-layered structure or a multi-layered structure including the above inorganic insulating materials.

The organic encapsulation layer 420 may alleviate inner stress of the first inorganic encapsulation layer 410 or the second inorganic encapsulation layer 430. The organic encapsulation layer 420 may include a polymer-based material. For example, the organic encapsulation layer 420 may include polyethylene terephthalate, polyethylene naphthalate, polycarbonate, polyimide, polyethylene sulfonate, polyoxymethylene, polyarylate, hexamethyldisiloxane, an acryl-based resin (e.g., polymethylmethacrylate, poly acrylic acid, etc.), or an arbitrary combination thereof.

The encapsulation layer 400 may have a multi-layered structure including the first inorganic encapsulation layer 410, the organic encapsulation layer 420, and the second inorganic encapsulation layer 430. In this case, even though cracks occur in the encapsulation layer 400, the cracks may not propagate between the first inorganic encapsulation layer 410 and the organic encapsulation layer 420, or between the organic encapsulation layer 420 and the second inorganic encapsulation layer 430. The encapsulation layer 400 may prevent or reduce external moisture, oxygen, or the like from penetrating the display area DA.

The touch sensor layer 500 may be disposed on the encapsulation layer 400. The touch sensor layer 500 may include a first touch electrode MT1, a first touch insulating layer 510, a second touch electrode MT2, and a second touch insulating layer 520. The first touch electrode MT1 may be directly disposed on the encapsulation layer 400. For example, the first touch electrode MT1 may be directly disposed on the second inorganic encapsulation layer 430 of the encapsulation layer 400. However, the present disclosure is not necessarily limited thereto.

For example, the touch sensor layer 500 may include an insulating layer (not shown) disposed between the first touch electrode MT1 and the encapsulation layer 400. In this case, the insulating layer may be disposed on the second inorganic encapsulation layer 430 of the encapsulation layer 400 to planarize a surface on which the first touch electrode MT1 and the like is disposed. The insulating layer may include an inorganic insulating material such as silicon oxide, silicon nitride, or silicon oxynitride. In an embodiment, the insulating layer may include an organic insulating material.

The first touch insulating layer 510 may be disposed on the first touch electrode MT1. The first touch insulating layer 510 may include an inorganic material or an organic material. In the case where the first touch insulating layer 510 includes an inorganic material, the first touch insulating layer 510 may include at least one of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride. In the case where the first touch insulating layer 510 includes an organic material, the first touch insulating layer 510 may include at least one of acrylic resin, methacrylic resin, polyisoprene, vinyl resin, epoxy resin, urethane resin, cellulose resin, and perylene resin.

The second touch electrode MT2 may be arranged on the first touch insulating layer 510. The second touch electrode MT2 may serve as a sensor that senses a user's touch input. The first touch electrode MT1 may serve as a connector that connects the adjacent second touch electrodes MT2 patterned in one direction. However, the present disclosure is not limited thereto. For example, both the first touch electrode MT1 and the second touch electrode MT2 may serve as sensors. In this case, the first touch electrode MT1 and the second touch electrode MT2 may be electrically connected to each other through a contact hole. In the case where both the first touch electrode MT1 and the second touch electrode MT2 serve as sensors, a resistance of a touch electrode is reduced and the touch sensing capability of the touch sensor layer 500 may increase.

According to an embodiment, the first touch electrode MT1 and the second touch electrode MT2 may include a structure through which light emitted from the light-emitting diode passes, for example, a mesh structure. In this case, the first touch electrode MT1 and the second touch electrode MT2 may not overlap an emission area of the light-emitting diode.

Each of the first touch electrode MT1 and the second touch electrode MT2 may include a metal layer or a transparent conductive layer. The metal layer may include at least one of molybdenum (Mo), silver (Ag), titanium (Ti), copper (Cu), aluminum (Al), and an alloy thereof. The transparent conductive layer may include a transparent conductive oxide such as indium tin oxide (ITO), zinc oxide (ZnO), and indium tin zinc oxide (ITZO), a conductive polymer such as poly(3,4-ethylenedioxythiophene) (PEDOT), a metal nanowire, a carbon nanotube, or graphene.

The second touch insulating layer 520 may be disposed on the second touch electrode MT2. The second touch insulating layer 520 may include an inorganic material or an organic material. In the case where the second touch insulating layer 520 includes an inorganic material, the second touch insulating layer 520 may include at least one of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride. In the case where the second touch insulating layer 520 includes an organic material, the second touch insulating layer 520 may include at least one material among acrylic resin, methacrylic resin, polyisoprene, vinyl resin, epoxy resin, urethane resin, cellulose resin, and perylene resin.

The light-controlling layer 600 may be disposed on the touch sensor layer 500. According to an embodiment, the light-controlling layer 600 may include the light-blocking layer 610, the lens layer 620, a low refractive layer 630, and a polarizing film 650. The light-controlling layer 600 may be disposed on the touch sensor layer 500. The light-controlling layer 600 may be directly disposed on the touch sensor layer 500, for example, the second touch insulating layer 520, which is the uppermost portion of the touch sensor layer 500. The light-blocking layer 610 and the lens layer 620 included in the light-controlling layer 600 may be directly disposed on the touch sensor layer 500.

The light-blocking layer 610 may include the upper opening 610OP corresponding to each of the green sub-pixel Pg, the blue sub-pixel Pb, and the red sub-pixel Pr. Specifically, the light-blocking layer 610 may include the first upper opening 610OP1 overlapping the first emission area EA1, the second upper opening 610OP2 overlapping the second emission area EA2, and the third upper opening 610OP3 overlapping the third emission area EA3. Light emitted from the first to third organic light-emitting didoes OLED1, OLED2, and OLED3 may be emitted through the upper opening 610OP of the light-blocking layer 610.

Because the upper opening 610OP of the light-blocking layer 610 is disposed to overlap the emission area, the upper opening 610OP may also overlap the lower opening 225OP of the bank layer 225. For example, the first upper opening 610OP1 of the light-blocking layer 610 may overlap the first lower opening 225OP1 of the bank layer 225, the second upper opening 610OP2 of the light-blocking layer 610 may overlap the second lower opening 225OP2 of the bank layer 225, and the third upper opening 610OP3 of the light-blocking layer 610 may overlap the third lower opening 225OP3 of the bank layer 225.

According to an embodiment, the width (or the size) of the upper opening 610OP of the light-blocking layer 610 may be greater than the width (or the size) of the emission area of the corresponding sub-pixel. For example, the size of the first upper opening 610OP1 of the light-blocking layer 610 may be greater than the size of the first lower opening 225OP1 of the bank layer 225. Likewise, the size of the second upper opening 610OP2 of the light-blocking layer 610 may be greater than the size of the second lower opening 225OP2 of the bank layer 225, and the size of the third upper opening 610OP3 of the light-blocking layer 610 may be greater than the size of the third lower opening 225OP3 of the bank layer 225.

The present disclosure, however, is not limited thereto. For example, the width (or the size) of the upper opening 610OP of the light-blocking layer 610 may be substantially the same as the width (or the size) of the emission area of the corresponding sub-pixel. For example, the size of the first upper opening 610OP1 of the light-blocking layer 610 may be substantially same as the size of the first lower opening 225OP1 of the bank layer 225. Likewise, the size of the second upper opening 610OP2 of the light-blocking layer 610 may be substantially the same as the size of the second lower opening 225OP2 of the bank layer 225, and the size of the third upper opening 610OP3 of the light-blocking layer 610 may be substantially the same as the size of the third lower opening 225OP3 of the bank layer 225.

The light-blocking layer 610 may include an organic insulating material. However, the present disclosure is not limited thereto. For example, the light-blocking layer 610 may include an inorganic insulating material such as silicon nitride or silicon oxide. For example, the light-blocking layer 610 may include an organic insulating material and an inorganic insulating material.

According to an embodiment, the light-blocking layer 610 may include a light-blocking material. For example, the light-blocking material of the light-blocking layer 610 may be black. The light-blocking material may include carbon black, carbon nanotubes, a resin or paste including black dye, metal particles, for example, nickel, aluminum, molybdenum, and an alloy thereof, metal oxide particles or metal nitride particles. Because the light-blocking layer 610 includes the light-blocking material, external light reflection caused by metal structures disposed below the light-blocking layer 610 may be reduced.

The lens layer 620 may be disposed inside the upper opening 610OP of the light-blocking layer 610. The lens layer 620 may be provided in plurality. The plurality of lens layers 620 may be disposed to respectively correspond to the first to third organic light-emitting diodes OLED1, OLED2, and OLED3. For example, each of the plurality of lens layers 620 may be disposed in each of the first upper opening 610OP1, the second upper opening 610OP2, and the third upper opening 610OP3 of the light-blocking layer 610. The plurality of lens layers 620 may be disposed apart from each other with the light-blocking layer 610 interposed therebetween. The lens layer 620 may overlap the organic light-emitting diode OLED and overlap the lower opening 225OP of the bank layer 225.

According to an embodiment, the lens layer 620 may have a concave upper surface. The upper surface of the lens layer 620 may include a concave curved surface, and the lower surface of the lens layer 620 may include a flat surface. The lens layer 620 may have a concave upper surface in the thickness direction of the substrate 100, or a progression direction of light emitted from the light-emitting diode. Accordingly, the upper surface of the lens layer 620 may be referred to as a surface facing the front surface of the display device 1, that is, a surface in contact with the low refractive layer 630 described below, and the lower surface of the lens layer 620 may be referred to as a surface facing the rear surface of the display device 1, that is, a surface in contact with the touch sensor layer 500.

Because the lens layer 620 has the concave upper surface and the flat lower surface, the thickness of the lens layer 620 may not be constant. According to an embodiment, a thickness d1 of a central portion of the lens layer 620 may be less than a thickness d2 of an edge portion of the lens layer 620 in the thickness direction of the substrate 100. The thickness of the lens layer 620 may gradually reduce from the edge portion to the central portion thereof in the thickness direction of the substrate 100. However, in an embodiment, the lens layer 620 may include some regions having the same thickness.

Referring to FIG. 6A, because the upper surface of the lens layer 620 has the concave surface, an imaginary fan shape may be formed using the concave upper surface of the lens layer 620. The imaginary fan shape may be defined by a radius r1 and a central angle θ. In this case, the radius r1 of the imaginary fan shape may be adjusted according to the resolution of the display device 1. According to example, the size of the upper opening 610OP of the light-blocking layer 610 may be adjusted according to the size of the lower opening 225OP of the bank layer 225 defining the emission area of the organic light-emitting diode OLED, and the radius r1 of the imaginary fan shape may be changed. The central angle θ of the imaginary fan shape may be about 10° to about 100°. When the central angle θ of the imaginary fan shape has a value within the above range, the lens layer 620 may have valid characteristics. For example, when the lens layer 620 has a refractive index of about 1.9, the lens layer 620 may have the most excellent efficiency within a range where the central angle θ of the imaginary fan shape is 10° to 30°.

According to an embodiment, a refractive index of the lens layer 620 may be about 1.6 to about 2.2. The refractive index of the lens layer 620 may be greater than the refractive index of the low refractive layer 630 disposed on the lens layer 620 and in direct contact with the lens layer 620. According to an embodiment, a difference between the refractive indices of the lens layer 620 and the refractive index of the low refractive layer 630 may be in a range from 0.1 to 1.2. The lens layer 620 having the above-mentioned refractive index may include an acryl-based resin or an epoxy-based resin. For example, the lens layer 620 may include polymethyl methacrylate, polyacrylic acid, ethylhexyl acrylate, pentafluoropropyl acrylate, polyethylene glycol dimethacrylate, or ethylene glycol dimethacrylate. However, the material included in the lens layer 620 is not limited thereto.

According to an embodiment, a thickness d3 of the light-blocking layer 610 may be equal to or less than the thickness d2 of the edge portion of the lens layer 620 in the thickness direction of the substrate 100. In other words, the upper surface of the light-blocking layer 610 may be disposed at a height equal to the upper surface of the lens layer 620, or disposed lower than the upper surface of the lens layer 620 in the thickness direction of the substrate 100. That is, the light-blocking layer 610 may not protrude further toward the front surface of the substrate 100 than the lens layer 620.

The lens layer 620 having the above structure may adjust a path of light emitted from the organic light-emitting diode OLED and diffuse light. Referring to FIG. 6B, first light LO1 emitted from the organic light-emitting diode OLED and incident to the lens layer 620 may be refracted at the interface between the lens layer 620 and the low refractive layer 630. For example, the first light LO1 incident to the central portion of the lens layer 620 may pass through the interface as it is and be emitted to the outside of the display device 1 in a straight manner, that is, without being diffused laterally, like second light LO2. In contrast, the first light LO1 incident to the non-central portion of the lens layer 620 may be refracted at the interface and be diffused in a lateral direction like the third light LO3 and emitted to the outside of the display device 1. That is, because light emitted from the organic light-emitting diode OLED may be laterally diffused and emitted through the lens layer 620, the lateral brightness of the display device 1 may be improved.

Particularly, as described above, the light-blocking layer 610 may be disposed below the upper surface of the lens layer 620 and may not protrude beyond the upper surface of the lens layer 620. If the light-blocking layer 610 is disposed to protrude beyond the upper surface of the lens layer 620, light laterally diffused through the lens layer 620 may be absorbed in the light-blocking layer 610. In contrast, in the display device 1 according to an embodiment, because the light-blocking layer 610 is not disposed in a progression direction of light which is laterally diffused, excellent light emission efficiency and lateral brightness improvement may be simultaneously implemented.

Likewise, referring to FIG. 6C, first incident light LI1 incident to the display device 1 from the outside may be refracted at the interface between the low refractive layer 630 and the lens layer 620. For example, the first incident light LI1 incident to the central portion of the lens layer 620 may pass through the interface as it is and enter the inside of the display device 1 in a straight manner, that is, without being diffused laterally, like second incident light LI2. In contrast, the first incident light LI1 incident to the non-central portion of the lens layer 620 may be refracted at the interface and diffused in the lateral direction like third incident light LI3 or fourth incident light LI4. External light incident to the display device 1 may be reflected at a metal layer such as the sub-pixel electrode 210 of the organic light-emitting diode OLED and be re-emitted to the outside. If the reflected light which is reflected from inside the display device 1, for example, from the sub-pixel electrode 210 of the organic light-emitting diode OLED, is re-emitted to the outside, the visibility and display quality of the display device 1 may be deteriorated.

In contrast, in the display device 1 having the structure shown in FIG. 6C, light refracted in the same direction as that of the fourth incident light LI4 through the lens layer 620 may be absorbed in the light-blocking layer 610. Likewise, because light refracted in the same direction as that of the third incident light LI3 through the lens layer 620 may be reflected by the sub-pixel electrode 210 and progress in the same direction as third incident light LI3', the light may be absorbed in the light-blocking layer 610. That is, because external light incident to the display device 1 and being diffused in the lateral direction through the lens layer 620 may be absorbed by the light-blocking layer 610, reflectance of external light may be efficiently reduced.

FIGS. 7A and 7B are graphs showing results related to refraction characteristics of the lens layer 620. Specifically, FIG. 7A is a graph showing brightness of emitted light according to changes in the viewing angle with respect to the front in the embodiments according to the present disclosure and the comparative examples, and FIG. 7B is a graph showing reflective brightness according to the changes in the viewing angle with respect to the front in the embodiments and the comparative examples. The x axis of FIG. 7A represents a measurement angle (°) of light, and the y axis represents brightness (a.u.) of emitted light. The x axis of FIG. 7B represents a measurement angle (°) of light, and the y axis represents reflective brightness (a.u.).

Embodiment 1 (40°) has a structure in which the central angle of the imaginary fan shape formed by the concave upper surface of the lens layer 620 is 40°, Embodiment 2 (30°) has a structure in which the central angle of the imaginary fan shape formed by the concave upper surface of the lens layer 620 is 30°, Embodiment 3 (24°) has a structure in which the central angle of the imaginary fan shape formed by the concave upper surface of the lens layer 620 is 24°, and Embodiment 4 (12°) has a structure in which the central angle of the imaginary fan shape formed by the concave upper surface of the lens layer 620 is 12°. Comparative Example REF has a structure in which the upper surface of the lens layer 620 has a flat surface instead of a concave curved surface. In this case, the lens layer included in each of the Embodiments 1 to 4 and the Comparative Example has a refractive index of about 1.9.

First, referring to FIG. 7A, although, within the range of light measurement angles of about 0° to about 30°, the comparative example REF has a slightly higher brightness of emitted light than the Embodiments 1 to 4, the efficiency of emitted light in the Embodiments 1 to 4 is not remarkably less than that of Comparative Example REF. Specifically, within a range of viewing angles from about 0° to about 30°, FIG. 7A shows that the Embodiments 1 to 4 have about 85 % to about 95 % of a brightness of emitted light compared to the Comparative Example REF. In addition, when the measurement angle of light is about 45°, FIG. 7A shows that the Embodiments 1 to 4 have about 55 % to about 60 % of a brightness of emitted light compared to the brightness of emitted light at a viewing angle of about 0°, and the Comparative Example has about 30 % of a brightness of emitted light compared to the brightness of emitted light at a viewing angle of about 0°. Particularly, when the measurement angle of light is 45° or more, FIG. 7A shows that that the efficiency of emitted light of the Embodiments 1 to 4 is greater than that of the Comparative Example REF. This means that, when viewed from the front, there is no remarkable difference in the efficiency of emitted light between the embodiments and the comparative example, but when viewed from the lateral side, the efficiency of emitted light of the embodiments is greater than the efficiency of emitted light of the comparative example. That is, the result of the comparison shown in FIG. 7A indicates that the structure in which the lens layer 620 having the concave upper surface is efficient in improving lateral brightness.

Next, referring to FIG. 7B, when a viewing angle is about 0°, FIG. 7B shows that reflective brightness of the Embodiments 1 to 4 is remarkably reduced compared to reflective brightness of the Comparative Example REF. Specifically, when a measurement angle of light is about 0° to about 15°, FIG. 7B shows that the reflective brightness of the Embodiments 1 to 4 is about 55 % to about 80 % compared to the reflective brightness of the Comparative Example REF. Particularly, FIG. 7B shows that the larger the central angle of the imaginary fan shape formed by the lens layer 620 having the concave upper surface, the lower the reflective brightness shows. That is, the result of the comparison shown in FIG. 7B indicates that the concave upper surface of the lens layer 620 may efficiently reduce reflectance of external light incident to the display device 1.

As a result, the display device 1 according to an embodiment may improve the lateral brightness and reduce reflection of external light by placing the lens layer 620 having the concave upper surface in the upper opening 610OP of the light-blocking layer 610, thereby improving the display quality.

Referring to FIG. 5 again, the low refractive layer 630 may be disposed on the light-blocking layer 610 and the lens layer 620. The low refractive layer 630 may planarize the light-controlling layer 600 by covering the light-blocking layer 610 and the lens layer 620. The low refractive layer 630 may be disposed on the lens layer 620 and be in direct contact with the lens layer 620. A refractive index of the low refractive layer 630 may be less than a refractive index of the lens layer 620. According to an embodiment, a difference between the refractive indices of the low refractive layer 630 and the refractive index of the lens layer 620 may be in a range from 0.1 to 1.2. For example, the refractive index of the low refractive layer 630 may be about 1 to about 1.6. However, the refractive index of the low refractive layer 630 is not limited thereto. The low refractive layer 630 may include a material having a refractive index of 1.6 or more as long as keeping a difference in refractive indices between the lens layer 620 and the low refractive layer 630 to be in a range from 0.1 to 1.2.

For example, the low refractive layer 630 may include acryl-based resin (e.g., polymethyl methacrylate, polyacrylic acid, and the like), ethylhexyl acrylate, pentafluoropropyl acrylate, polyethylene glycol dimethacrylate, poly(ethylene glycol) dimethacrylate or ethylene glycol dimethacrylate.

The polarizing film 650 may be disposed on the low refractive layer 630, and an adhesive layer 640 may be disposed between the low refractive layer 630 and the polarizing film 650. The adhesive layer 640 may adhere the low refractive layer 630 to the polarizing film 650. For example, the adhesive layer 640 may include a transparent adhesive member such as a pressure sensitive adhesive (PSA) film, an optically clear adhesive (OCA) film, or an optically clear resin (OCR).

The polarizing film 650 may be a structure which prevents external light from being reflected from the display device 1 and prevents the reduction of the visibility of the image provided from the display device 1. That is, the polarizing film 650 may serve as an anti-reflector. The polarizing film 650 may polarize incident light by allowing only components of the incident light that vibrate along a designated polarizing axis to pass through. The polarizing film 650 may include a linear polarizer and a phase retarder, and the polarizing film 650 may be a circular polarizer. The display device 1 according to an embodiment may reduce reflection of external light more effectively and thus improve the display quality by further including the polarizing film 650 together with the light-blocking layer 610 and the lens layer 620 having the concave upper surface.

The cover window 700 may be disposed on the polarizing film 650 with the adhesive layer OCA therebetween. The cover window 700 may be attached to the light-controlling layer 600 using the adhesive layer OCA. The adhesive layer OCA may include an optically clear adhesive. The cover window 700 may be transparent. The cover window 700 may include at least one of glass, sapphire, and plastic. For example, the cover window 700 may be ultra-thin glass (UTG) or colorless polyimide (CPI).

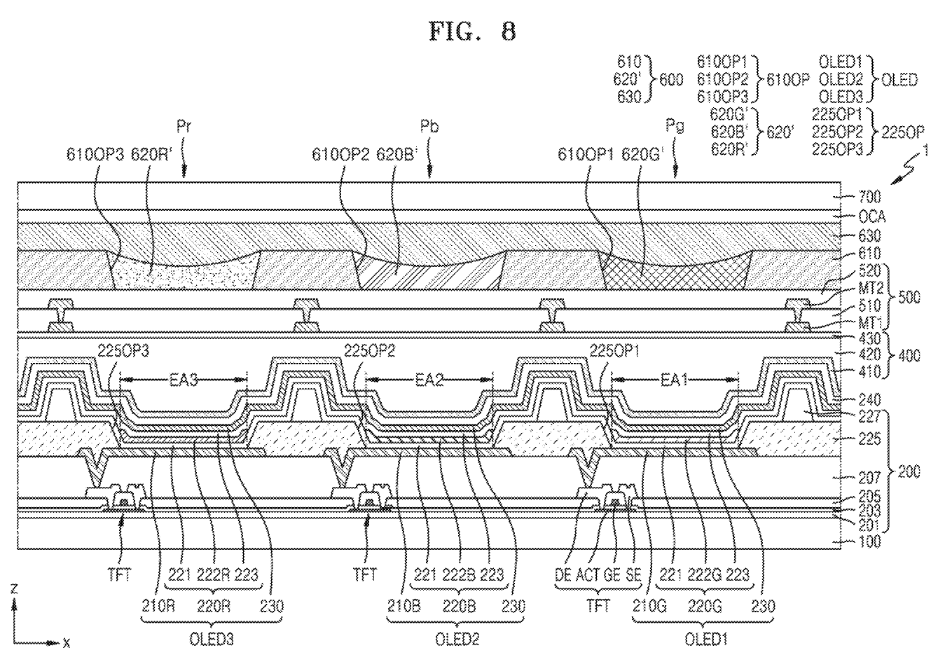

FIG. 8 is a schematic cross-sectional view of the display device according to an embodiment. A display device shown in FIG. 8 may be identical or similar to the display device with reference to FIGS. 4 to 6C, except a lens layer 620’. The reference characters of FIG. 8, which are identical to those of FIGS. 4 to 6C, may indicate the same elements, and the differences from FIGS. 4 to 6C are mainly described below.

Referring to FIG. 8, the light-controlling layer 600 may include the light-blocking layer 610, the lens layer 620', and the low refractive layer 630. The lens layer 620' may be disposed inside the upper opening 610OP of the light-blocking layer 610. The lens layer 620' may be provided in plurality and each of the plurality of lens layers 620' may be disposed to correspond to the first to third organic light-emitting diodes OLED1, OLED2, and OLED3, respectively. For example, the lens layer 620' may include a first lens layer 620G' corresponding to the green sub-pixel Pg and disposed in the first upper opening 610OP1, a second lens layer 620B' corresponding to the blue sub-pixel Pb and disposed in the second upper opening 610OP2, and a third lens layer 620R' corresponding to the red sub-pixel Pr and disposed in the third upper opening 610OP3. The first lens layer 620G', the second lens layer 620B', and the third lens layer 620R' may be disposed apart from each other with the light-blocking layer 310 interposed therebetween. The lens layer 620' may overlap the organic light-emitting diode OLED and the lower opening 225OP of the bank layer 225.

According to an embodiment, each of the first lens layer 620G', the second lens layer 620B', and the third lens layer 620R' may have a concave upper surface. The upper surface of each of the first lens layer 620G', the second lens layer 620B', and the third lens layer 620R' may include a concave curved surface, and the lower surface of each of the first lens layer 620G', the second lens layer 620B', and the third lens layer 620R' may include a flat surface. In addition, the upper surface of the light-blocking layer 610 may be disposed at a height equal to the upper surface of each of the first lens layer 620G', the second lens layer 620B', and the third lens layer 620R', or disposed lower than the upper surface of each of the first lens layer 620G', the second lens layer 620B', and the third lens layer 620R' in the thickness direction of the substrate 100.

In an embodiment, the lens layer 620' may include a color filter material. Specifically, the lens layer 620' may include a color filter material, such as pigment or dye, and base resin. Each of the first lens layer 620G', the second lens layer 620B', and the third lens layer 620R' may include a color filter material corresponding to a color of light emitted from the organic light-emitting diode OLED. For example, the first lens layer 620G' may be a green color filter including green pigment or green dye. The second lens layer 620B' may be a blue color filter including blue pigment or blue dye. The third lens layer 620R' may be a red color filter including red pigment or red dye.

Because the color filter may allow only light of a specific color to pass through and absorb the rest of light, when the lens layer 620' includes the color filter having a specific color, a portion of light, which represents different colors from the color filter of the specific color, incident to the display device 1 may be absorbed in the lens layer 620'. That is, the lens layer 620' including the color filter material may reduce the reflection of external light.

Accordingly, the display device 1 according to an embodiment may improve lateral brightness and reduce the reflection of external light by forming the concave upper surface of the lens layer 620', and further improve the display quality by forming the lens layer 620’ to include the color filter material.

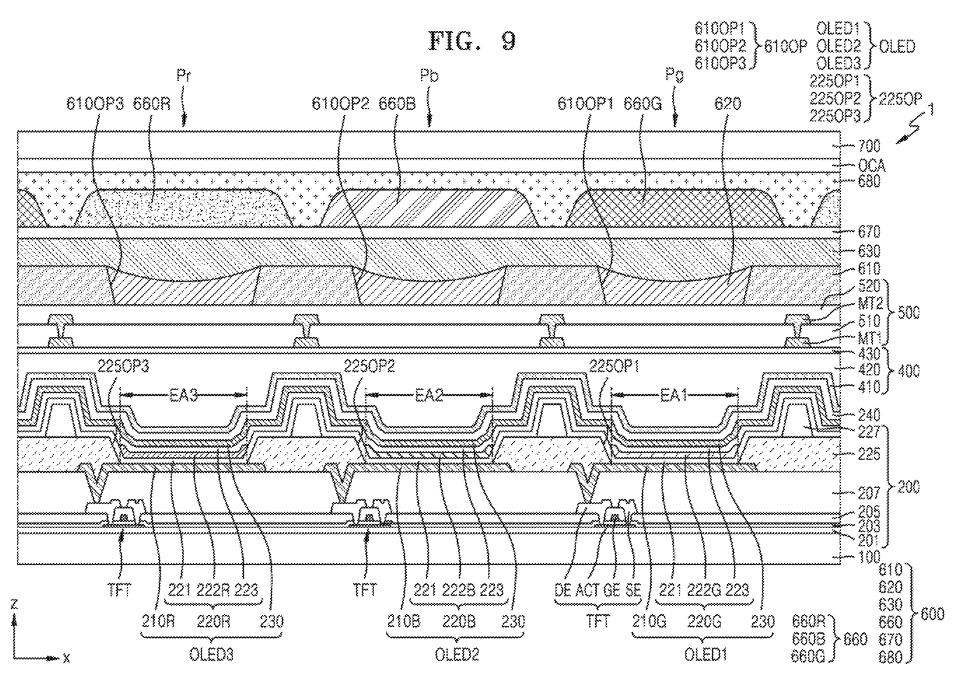

FIG. 9 is a schematic cross-sectional view of a portion of the display device 1 according to an embodiment. A display device shown in FIG. 9 may be identical or similar to the display device with reference to FIGS. 4 to 6C, except a color filter layer 660 and an overcoat layer 680. The reference characters of FIG. 9, which are identical to those of FIGS. 4 to 6C, may indicate the same elements, and the differences from FIGS. 4 to 6C are mainly described below.

Referring to FIG. 9, the light-controlling layer 600 may include the light-blocking layer 610, the lens layer 620, the low refractive layer 630, an inorganic insulating layer 670, the color filter layer 660, and the overcoat layer 680. The light-blocking layer 610 may be disposed on the touch sensor layer 500, and the lens layer 620 may be disposed in the upper opening 610OP of the light-blocking layer 610. According to an embodiment, the lens layer 620 may have a concave upper surface. The upper surface of the light-blocking layer 610 may be disposed at a height equal to the upper surface of the lens layer 620, or disposed lower than the upper surface of the lens layer 620 in the thickness direction of the substrate 100. The low refractive layer 630 may be disposed on the light-blocking layer 610 and the lens layer 620. The low refractive layer 630 may include a material having a refractive index less than that of the lens layer 620, and a difference in refractive indices between the lens layer 620 and the low refractive layer 630 may be in a range from 0.1 to 1.2.

The color filter layer 660 may be disposed on the low refractive layer 630. According to an embodiment, the inorganic insulating layer 670 may be disposed between the low refractive layer 630 and the color filter layer 660. The inorganic insulating layer 670 may include an inorganic material such as silicon oxide, silicon nitride, or silicon oxynitride. However, depending on the design of the display device, the inorganic insulating layer 670 may be omitted.

The color filter layer 660 may include a first color filter 660G corresponding to the green sub-pixel Pg, a second color filter 660B corresponding to the blue sub-pixel Pb, and a third color filter 660R corresponding to the red sub-pixel Pr. According to an embodiment, the first color filter 660G may be a green color filter, the second color filter 660B may be a blue color filter, and the third color filter 660R may be a red color filter.

Each color filter may be disposed to correspond to the organic light-emitting diode OLED. For example, the first color filter 660G may be disposed on the first organic light-emitting diode OLED1 and overlap the first lower opening 225OP1 of the bank layer 225 and the first upper opening 610OP1 of the light-blocking layer 610. Likewise, the second color filter 660B may be disposed on the second organic light-emitting diode OLED2 and overlap the second lower opening 225OP2 of the bank layer 225 and the second upper opening 610OP2 of the light-blocking layer 610. The third color filter 660R may be disposed on the third organic light-emitting diode OLED3 and overlap the third lower opening 225OP3 of the bank layer 225 and the third upper opening 610OP3 of the light-blocking layer 610.

According to an embodiment, the first color filter 660G, the second color filter 660B, and the third color filter 660R may be disposed apart from each other. The overcoat layer 680, which will be described below, may fill gaps between color filters disposed adjacent to each other. For example, the overcoat layer 680 may fill a first gap between the first color filter 660G and the second color filter 660B, fill a second gap between the second color filter 660B and the third color filter 660R, and fill a third gap between the third color filter 660R and the first color filter 660G. However, the present embodiment is not limited thereto. For example, edges of two color filters disposed adjacent to each other may overlap each other in an area correspond to the light-blocking layer 610, for example, in non-emission areas.

As described above, the color filter layer 660 may allow only light of a specific color to pass through and absorb rest of the light. Accordingly, when the light-controlling layer 600 includes the color filter layer 660, a portion of light, which represents different colors from the color filter of the specific color, incident to the display device 1 may be absorbed in the color filter layer 660. That is, the color filter layer 660 may reduce the reflection of external light.

Accordingly, the display device 1 according to an embodiment may improve lateral brightness and reduce the reflection of external light by forming the concave upper surface of the lens layer 620, and further improve the display quality by forming the color filter layer 660 on the lens layer 620.

The overcoat layer 680 may be disposed on the color filter layer 660. The overcoat layer 680 may planarize the upper surface of the color filter layer 660. That is, the overcoat layer 680 may be integrally formed over the first color filter 660G, the second color filter 660B, and the third color filter 660R. The overcoat layer 680 may be a colorless and light-transmitting layer that does not have a color in a visible light band. The overcoat layer 680 may include a colorless and light-transmissive organic material such as an acryl-based resin. The adhesive layer OCA and the cover window 700 may be disposed on the overcoat layer 680.

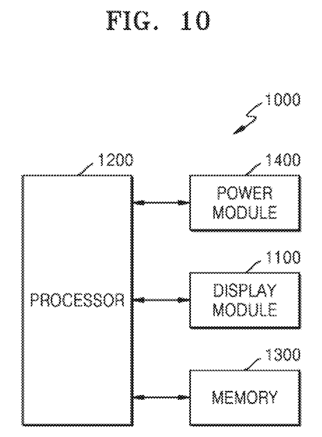

FIG. 10 is a block diagram of an electronic device according to an embodiment.

Referring to FIG. 10, the electronic device 1000 according to an embodiment may include a display module 1100, a processor 1200, a memory 1300, and a power module 1400.

The electronic device 1000 may output various information through the display module 1100.

The processor 1200 may include at least one of a central processing unit (CPU), an application processor (AP), a graphic processing unit (GPU), a communication processor (CP), an image signal processor (ISP), and a controller. According to an embodiment, the processor 1200 may be divided into two or more components from a functional or structural perspective. For example, the processor 1200 may include a main processor in the form of a first driving chip, including a central processing unit, and an auxiliary processor in the form of a second driving chip, including a controller which receives image signals from the main processor and processes the image signals to meet interface specifications of the display module 1100.

The memory 1300 may include at least one of a non-volatile memory and a volatile memory. The memory 13 may store data information required for operations of the processor 1200 or the display module 1100. When the processor 1200 executes an application stored in the memory 1300, an image data signal or an input control signal may be transferred to the display module 1100, and the display module 1100 may process a provided signal and output image information through a display screen.

The power module 1400 may include a power supply module such as a power adapter or a battery unit, and a power converting module converting power supplied by the power supply module and generating power required for operations of the electronic device 1000. Power conversion by the power converting module may include, but is not limited to, DC-DC conversion, AC-DC conversion, and DC-AC conversion.

At least one of elements of the electronic device 1000 may be included in the display device according to the above-described embodiments. In addition, some of individual modules functionally included in one module may be included in the display device, and some other may be provided separately from the display device. For example, the display device may include the display module 1100 and the auxiliary processor of the processor 1200, and the main processor of the processor 1200, the memory 1300 and the power module 1400 may be provided in the form of another device within the electronic device 1000 other than the display device. The power module 1400 may be provided in the display device and may provide power to the processor 1200 and the memory 1300 which are provided within the electronic device 1000 other than the display device.

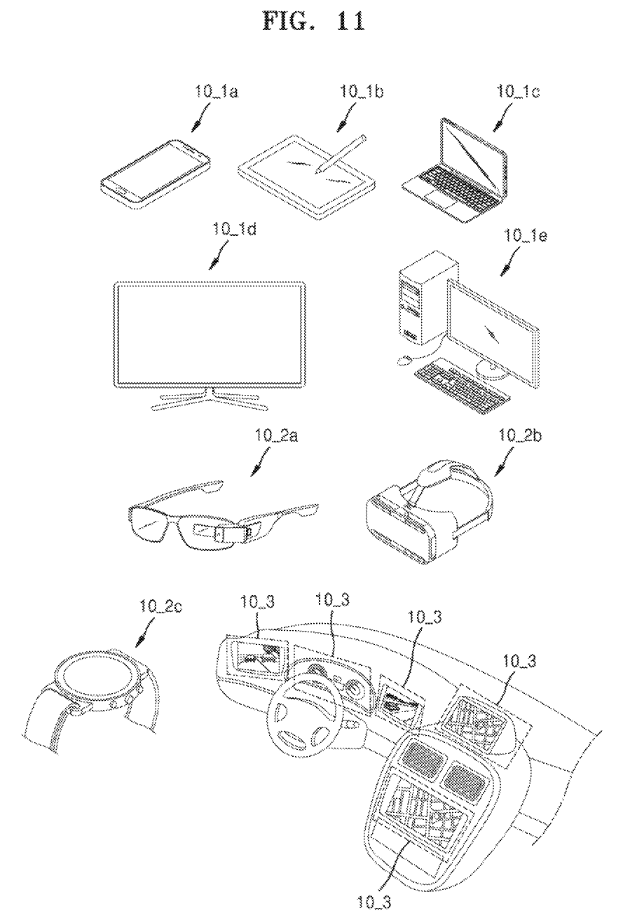

FIG. 11 is a schematic view of electronic devices according to various embodiments.

A display device according to embodiments is a device displaying moving images or still images and is applicable to various electronic devices. Referring to FIG. 11, the various electronic devices employing the display device according to the embodiments may include not only electronic devices for displaying images, such as a smartphone 10_1a, a tablet personal computer (PC) 10_1b, a laptop computer 10_1c, a TV 10_1d, and a desk monitor 10_1e, but also wearable electronic devices including a display module, such as a smart glasses 10_2a, a head mount display 10_2b, and a smart watch 10_2c. The electronic devices including the display device according to embodiments may further include vehicle electronic devices 10_3 including a display module, such as an instrument panel of an automobile, a center fascia, a center information display (CID) disposed on a dashboard, and a room mirror display. The electronic device 1000 that includes the display device according to embodiments is not limited to the above-described devices.

The electronic device of FIG. 11 may include the elements shown in FIG. 10. For example, the smartphone 10_1a may include the display module 1100, the processor 1200, the memory 1300, and the power module 1400 shown in FIG. 10. The smartphone 10_1a may further include a battery device. Power provided from the battery device may be converted through the power module 1400 and provided to the processor 1200, the memory 1300, and the display module 1100. The display device applied to the smartphone 10_1a may include the display module 1100 and further include the power module 1400. Although the processor 1200 and the memory 1300 may be provided in a form of a chip mounted on a motherboard, which is an external device, the embodiment is not limited thereto.

According to embodiments, the display device having improved display quality and an electronic device including the same may be provided. However, this effect is an example, and the scope of the disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While the present disclosure has been described with reference to the drawings and embodiment thereof, it will be understood by those of ordinary skill in the art that various changes in form and details may be made thereto without departing from the spirit and scope of the present disclosure as set forth and defined by the following claims.

What is claimed is:

1. A display device comprising:
a substrate;
a display layer disposed on the substrate and including a light-emitting diode and a bank layer, the bank layer including a lower opening defining an emission area of the light-emitting diode; and
a light-controlling layer disposed on the display layer and including a light-blocking layer and a lens layer, the light-blocking layer including an upper opening overlapping the lower opening, and the lens layer filling the upper opening,
wherein the lens layer has a concave upper surface in a thickness direction of the substrate.

2. The display device of claim 1, wherein, in the thickness direction of the substrate, a thickness of a central portion of the lens layer is less than a thickness of an edge portion of the lens layer.

3. The display device of claim 2, wherein, in the thickness direction of the substrate, a thickness of the light-blocking layer is equal to or less than the thickness of the edge portion of the lens layer.

4. The display device of claim 1, wherein, in the thickness direction of the substrate, an upper surface of the light-blocking layer is disposed at a height equal to an upper surface of the lens layer or disposed under the upper surface of the lens layer.

5. The display device of claim 1, wherein the light-emitting diode is provided in plurality, and the lens layer is provided in plurality,
wherein each of the plurality of lens layers is disposed on a corresponding light-emitting diode among the plurality of light-emitting diodes, and
wherein two lens layers disposed adjacent to each other among the plurality of lens layers are disposed apart from each other, and the light-blocking layer is interposed between the two lens layers.

6. The display device of claim 1, wherein, when an imaginary fan is formed using the concave upper surface of the lens layer, a central angle of the imaginary fan is about 10° to about 100°.

7. The display device of claim 1, wherein a refractive index of the lens layer is about 1.6 to about 2.2.

8. The display device of claim 1, wherein the light-controlling layer further includes a low refractive layer disposed on the light-blocking layer and the lens layer and in direct contact with the lens layer, and
wherein a refractive index of the lens layer is greater than a refractive index of the low refractive layer.

9. The display device of claim 8, wherein a difference between the refractive index of the lens layer and the refractive index of the low refractive layer is from 0.1 to 1.2.

10. The display device of claim 1, wherein the light-controlling layer further includes a polarizing film disposed on the light-blocking layer and the lens layer.

11. The display device of claim 1, wherein the lens layer includes a color filter material.

12. The display device of claim 1, wherein the light-controlling layer further includes a color filter layer disposed on the light-blocking layer and the lens layer.

13. The display device of claim 12, wherein the light-controlling layer further includes an overcoat layer disposed on the color filter layer,
wherein the color filter layer includes a plurality of color filters, and each of the plurality of color filters is disposed apart from each other, and
wherein the overcoat layer fills gaps between color filters disposed adjacent to each other.

14. A display device comprising:
a substrate;
a display layer including a light-emitting diode disposed on the substrate;
an input-sensing layer disposed on the display layer; and
a light-controlling layer disposed on the input-sensing layer,
wherein the light-controlling layer includes:
a light-blocking layer including an opening overlapping an emission area of the light-emitting diode;
a lens layer disposed in the opening of the light-blocking layer; and
a low refractive layer disposed on the light-blocking layer and the lens layer, and having a refractive index less than the lens layer, and
wherein, in a thickness direction of the substrate, an upper surface of the lens layer facing the low refractive layer has a concave curved surface.

15. The display device of claim 14, wherein, in the thickness direction of the substrate, an upper surface of the light-blocking layer is disposed at a height equal to the upper surface of the lens layer or disposed under the upper surface of the lens layer.

16. The display device of claim 14, wherein the light-controlling layer further includes a polarizing film disposed on the low refractive layer.

17. The display device of claim 14, wherein the lens layer includes a color filter material.

18. The display device of claim 14, wherein the light-controlling layer further includes a color filter layer disposed on the low refractive layer.

19. An electronic device comprising:
a display device providing images; and
a housing accommodating the display device,
wherein the display device includes:
a substrate;
a display layer disposed on the substrate and including a light-emitting diode and a bank layer, the bank layer including a lower opening defining an emission area of the light-emitting diode; and
a light-controlling layer disposed on the display layer and including a light-blocking layer and a lens layer, the light-blocking layer including an upper opening overlapping the lower opening, and the lens layer filling the upper opening,
wherein the lens layer has a concave upper surface in a thickness direction of the substrate.

20. The electronic device of claim 19, wherein in the thickness direction of the substrate, an upper surface of the light-blocking layer is disposed at a height equal to an upper surface of the lens layer or disposed under the upper surface of the lens layer.
